(19) United States
(12) Patent Application Publication
(10) Pub. No.: US 2013/0234338 A1
(43) Pub. Date: Sep. 12, 2013

(54) SEMICONDUCTOR DEVICE AND METHOD FOR MANUFACTURING THE SAME

(71) Applicants: Tsuneo UENAKA, Mie-ken (JP); Yoshiro Shimojo, Mie-ken (JP)

(72) Inventors: Tsuneo UENAKA, Mie-ken (JP); Yoshiro Shimojo, Mie-ken (JP)

(73) Assignee: Kabushiki Kaisha Toshiba, Tokyo (JP)

(21) Appl. No.: 13/600,892

(22) Filed: Aug. 31, 2012

(30) Foreign Application Priority Data
Mar. 7, 2012 (JP) 2012-051045

(51) Int. Cl. H01L 23/538; H01L 21/768

(52) U.S. Cl. CPC H01L 23/5384; H01L 21/76877
USPC 257/774; 438/675

(57) ABSTRACT

According to one embodiment, a semiconductor device includes a plurality of contact electrodes that reach corresponding conductive layers. Each of the contact electrodes includes a columnar portion, a stopper, and a first connection portion. The columnar portion extends in a stacked direction of the stacked body. The stopper covers the side of the columnar portion. The first connection portion is provided at a lower edge of the columnar portion. The first connection portion is in contact with the corresponding conductive layer. A cross-section dimension of the first connection portion in a direction orthogonal to the stacked direction is larger than a cross-section of the lower edge of the columnar portion. An etching rate of a material for the stopper is lower than an etching rate of a material for the first insulating layer.

### CROSS-REFERENCE TO RELATED APPLICATIONS

This application is based upon and claims the benefit of priority from the prior Japanese Patent Application No. 2012-051045, filed on Mar. 7, 2012; the entire contents of which are incorporated herein by reference.

### FIELD

Embodiments described herein relate generally to a semiconductor device and a method for manufacturing the same.

### BACKGROUND

There is a semiconductor device having a stacked body in which a plurality of conductive layers and a plurality of insulating layers are alternately stacked.

In such a semiconductor device, a contact electrode is provided to connect the plurality of stacked conductive layers to an upper layer interconnect. The contact electrode is provided in a hole formed by etching.

However, as a depth dimension of the hole becomes larger, the cross-section dimension of the lower edge may be smaller. Therefore, the contact area of the contact electrode and the conductive layer becomes smaller, which may undesirably increase the electric resistance.

### BRIEF DESCRIPTION OF THE DRAWINGS

FIG. 1 is a schematic perspective view for illustrating the semiconductor device 1 according to the first embodiment;

FIG. 2 is a schematic perspective view for illustrating a configuration of the element region is provided in the semiconductor device 1 according to the first embodiment;

FIG. 3 is a schematic view for illustrating a cross-section of a portion where the silicon body 20 passes through the conductive layers WL1 to WL4 and the interlayer insulating layers 25;

FIGS. 4A to 4C are schematic cross-sectional views for illustrating the contact electrode according to the embodiment;

FIGS. 5A and 5B are schematic cross-sectional views for illustrating the contact electrode according to the comparative example;

FIGS. 6A to 6D are schematic process cross-sectional views for illustrating the forming of elements provided in the contact region 1b;

FIGS. 7A and 7B are schematic process cross-sectional views for illustrating the forming of elements provided in the contact region 1b;

FIGS. 8 A to 8D are schematic process cross-sectional views for illustrating the forming of elements provided in the contact region 1b;

FIGS. 9A and 9B are schematic process cross-sectional views for illustrating the forming of elements provided in the contact region 1b;

FIGS. 10A to 10D are schematic process cross-sectional views for illustrating the forming of elements provided in the contact region 1b;

FIGS. 11A and 11B are schematic process cross-sectional views for illustrating the forming of elements provided in the contact region 1b; and

FIG. 12 is a schematic perspective view for illustrating another configuration of an element region 1a1 provided in the semiconductor device 1 according to the first embodiment.

### DETAILED DESCRIPTION

In general, according to one embodiment, a semiconductor device includes a stacked body in which a plurality of conductive layers and a plurality of first insulating layers are alternately stacked. The semiconductor device includes a plurality of contact electrodes that reach corresponding conductive layers. Each of the contact electrodes includes a columnar portion, a stopper, and a first connection portion. The columnar portion extends in a stacked direction of the stacked body. The stopper covers the side of the columnar portion. The first connection portion is provided at a lower edge of the columnar portion. The first connection portion is in contact with the corresponding conductive layer. A cross-section dimension of the first connection portion in a direction orthogonal to the stacked direction is larger than a cross-section of the lower edge of the columnar portion. An etching rate of a material for the stopper is lower than an etching rate of a material for the first insulating layer.

Hereinafter, with reference to drawings, embodiments will be described. In the drawings, like components are denoted by like reference numerals and detailed description thereof will be omitted.

Hereinafter, for the sake of description, an XYZ orthogonal coordinate system is introduced. In the coordinate system, two directions which are parallel to a main surface of a substrate 10 and orthogonal to each other are referred to as an X-direction and a Y-direction and a direction which is orthogonal to both the X-direction and the Y-direction is referred to as a Z-direction.

Further, in the following embodiment, silicon is illustrated as an example of the semiconductor, but a semiconductor other than silicon may be used.

### First Embodiment

First, a semiconductor device 1 according to a first embodiment will be illustrated.

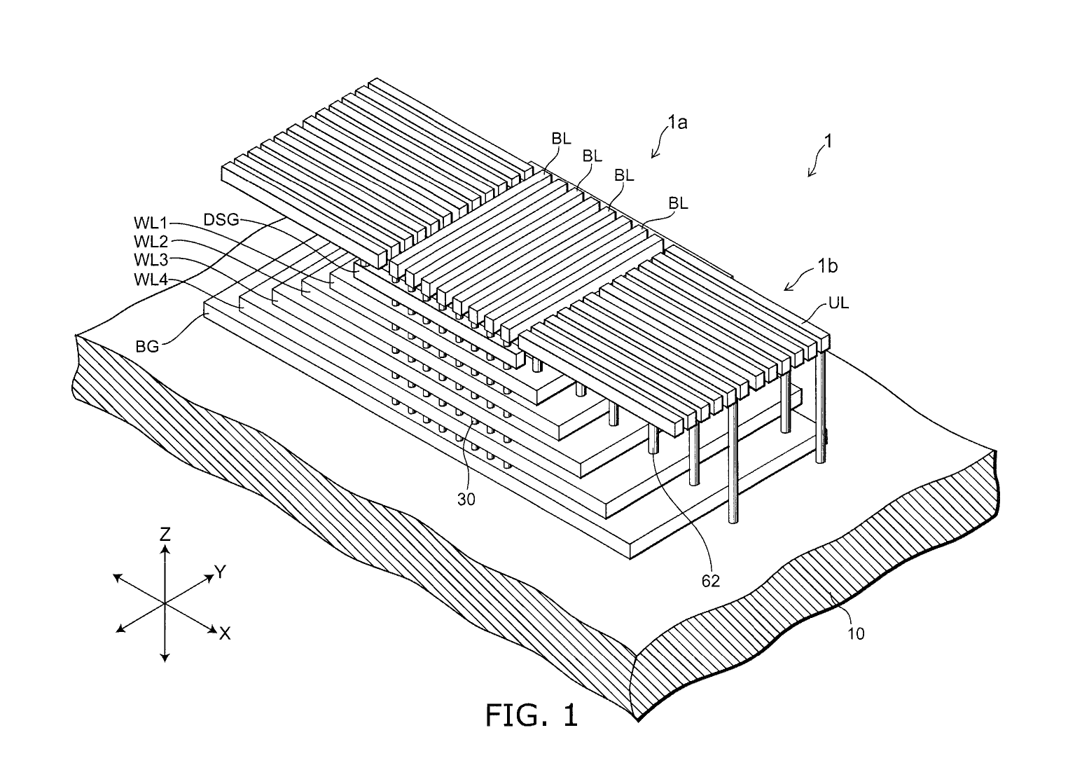

FIG. 1 is a schematic perspective view for illustrating the semiconductor device 1 according to the first embodiment.

In FIG. 1, in order to simplify the drawing, an insulated part is omitted.

As illustrated in FIG. 1, the semiconductor device 1 according to the first embodiment has an element region 1a and a contact region 1b. The element region is a region in which semiconductor elements are provided and the contact region 1b is a region in which contact electrodes 62 for connecting conductive layers WL1 to WL4 to upper layer interconnects UL are provided.

Further, since a known technology may be applied to a peripheral circuit region in which a peripheral circuit for driving the semiconductor elements (memory cells) provided in the element region 1a is provided or the upper layer interconnects UL, the description thereof will be omitted.

First, a configuration of the element region 1a will be illustrated.

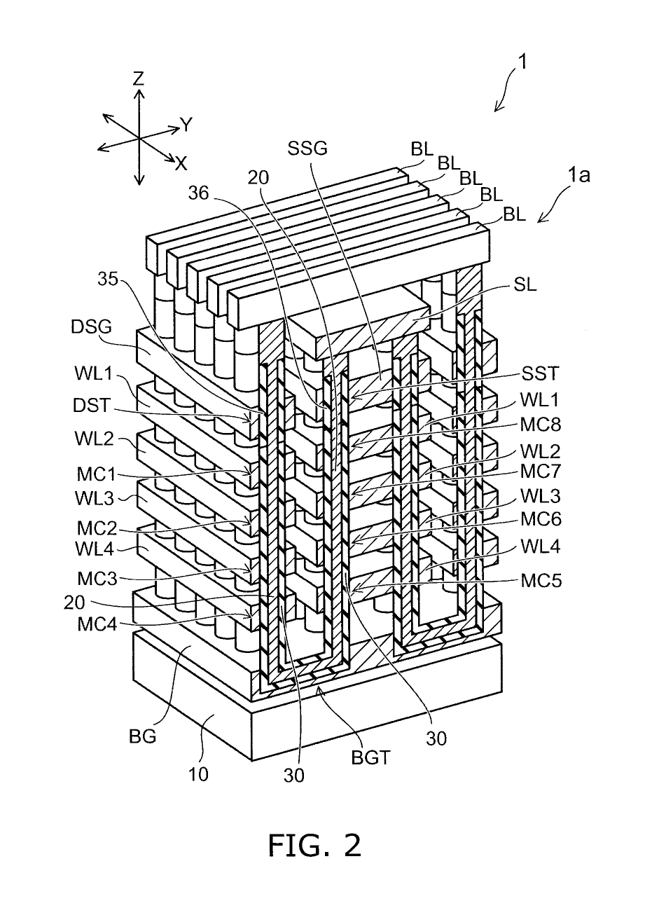

FIG. 2 is a schematic perspective view for illustrating a configuration of the element region 1a provided in the semiconductor device 1 according to the first embodiment.

FIG. 2 illustrates a configuration of a memory cell array provided in the element region 1a as an example.

In FIG. 2, in order to simplify the drawing, an insulated part other than an insulating film formed in a memory hole will be omitted.

As illustrated in FIG. 2, a back gate BG is provided on a substrate 10 through an insulating layer which is not illustrated. The back gate BG is, for example, a conductive silicon layer to which an impurity is added. On the back gate BG, a plurality of conductive layers WL1 to WL4 and the insulating layers which are not illustrated are alternately stacked. The number of layers of conductive layers WL1 to WL4 may be arbitrary. In the embodiment, for example, the number of layers is four. The conductive layers WL1 to WL4 are, for example, conductive silicon layers to which an impurity is added.

The conductive layers WL1 to WL4 are divided into a plurality of blocks by grooves extending in the X-direction. On an uppermost conductive layer WL1 in an arbitrary block, a drain side selective gate DSG is provided through an insulating layer which is not illustrated. The drain side selective gate DSG is, for example, a conductive silicon layer to which an impurity is added. On an uppermost conductive layer WL1 in another block adjacent to the arbitrary block, a source side selective gate SSG is provided through an insulating layer which is not illustrated. The source side selective gate SSG is, for example, a conductive silicon layer to which an impurity is added.

On the source side selective gate SSG, a source line SL is provided with an insulating layer, which is not illustrated, therebetween. The source line is, for example, a conductive silicon layer to which an impurity is added. Alternatively, the source line SL may use a metal material. On the source line SL and the drain side selective gate DSG, a plurality of bit lines BL are provided through an insulating layer which is not illustrated. The bit lines BL extend in the Y-direction.

In the above-mentioned stacked body on the substrate 10, a plurality of U-shaped memory holes are provided. In the block including the drain side selective gate DSG, a memory hole that passes through the drain side selective gate DSG and the conductive layers WL1 to WL4 disposed below the drain side selective gate DSG and extends in the Z-direction is formed. In the block including the source side selective gate SSG, a memory hole that passes through the source side selective gate SSG and the conductive layers WL1 to WL4 disposed below the source side selective gate SSG and extends in the Z-direction is formed. Both the memory holes are connected by a memory hole that is formed in the back gate BG and extends in the Y-direction.

Inside the memory hole, a silicon body 20 is provided as a U-shaped semiconductor layer. In an inner wall of the memory hole between the drain side selective gate DSG and the silicon body 20, a gate insulating film 35 is formed. On an inner wall of the memory hole between the source side selective gate SSG and the silicon body 20, a gate insulating film 36 is formed. On an inner wall of the memory hole between each of the conductive layers WL1 to WL4 and the silicon body 20, an insulating film 30 is formed. Also on an inner wall of the memory hole between the back gate BG and the silicon body 20, an insulating film 30 is formed. The insulating film 30 has, for example, an ONO (oxide-nitride-oxide) structure in which a silicon nitride film is interposed between a pair of silicon dioxide films.

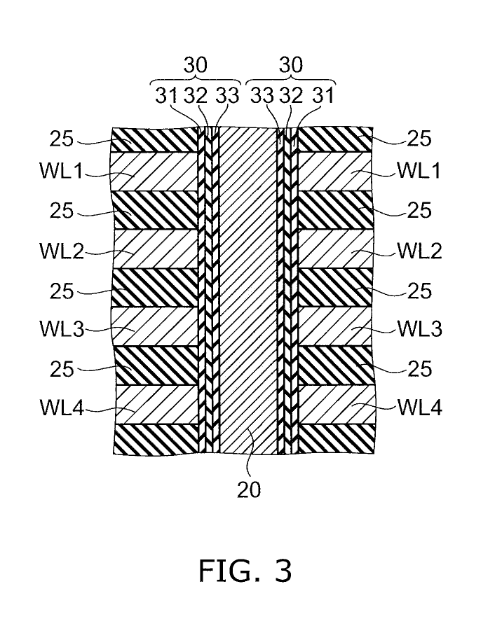

FIG. 3 is a schematic view for illustrating a cross-section of a portion where the silicon body 20 passes through the conductive layers WL1 to WL4 and the interlayer insulating layers 25 (corresponds to an example of a first insulating layer).

Between the conductive layers WL1 to WL4 and the silicon body 20, an insulating film 31, a charge storage layer 32, and an insulating film 33 are provided in this order from the conductive layers WL1 to WL4. The insulating film 31 is in contact with the conductive layers WL1 to WL4, the insulating film 33 is in contact with the silicon body 20, and the charge storage layer 32 is provided between the insulating film 31 and the insulating film 33.

The silicon body 20 functions as a channel, the conductive layers WL1 to WL4 function as control gates, and the charge storage layer 32 functions as a data memory layer that stores charges injected from the silicon body 20. Specifically, at intersections of the silicon body 20 and the conductive layers WL1 to WL4, memory cells having a structure where the control gate encloses the channel are formed.

The semiconductor device 1 is a non-volatile semiconductor memory device that may freely delete and write data and store the stored contents even when the power is turned off. For example, the memory cell is a memory cell having a charge trap structure. The charge storage layer 32 has a plurality of traps that trap the charges (electrons), and for example, is formed of a silicon nitride film. The insulating film 33 is, for example, formed of a silicon dioxide film. When the charges are injected from the silicon body 20 into the charge storage layer 32 or the charges stored in the charge storage layer 32 are diffused to the silicon body 20, the insulating film 33 become a potential barrier. The insulating film 31 is, for example, formed of a silicon dioxide film and prevents the charges stored in the charge storage layer 32 from being diffused to the conductive layers WL1 to WL4.

Referring to FIG. 2 again, a gate insulating film 35 is provided between the silicon body 20 that passes through the drain side selective gate DSG and the drains side selective gate DSG to configure a drain side selective transistor DST. An upper edge of each silicon body 20 that upwardly protrudes from the drain side selective gate DSG is connected to a corresponding bit line BL.

A gate insulating film 36 is provided between the silicon body 20 that passes through the source side selective gate SSG and the source side selective gate SSG to configure a source side selective transistor SST. An upper edge of each silicon body 20 that upwardly protrudes from the source side selective gate SSG is connected to a source line SL.

The back gate BG, the silicon body 20 provided in the back gate BG, and the insulating film 30 between the back gate BG and the silicon body 20 configure a back gate transistor BGT.

Between the drain side selective transistor DST and the back gate transistor BGT, a memory cell MC1 that has the conductive layer WL1 as a control gate, a memory cell MC2 that has the conductive layer WL2 as a control gate, a memory cell MC3 that has the conductive layer WL3 as a control gate, and a memory cell MC4 that has the conductive layer WL4 as a control gate are provided.

Between the back gate transistor BGT and the source side selective transistor SST, a memory cell MC5 that has the conductive layer WL4 as a control gate, a memory cell MC6 that has the conductive layer WL3 as a control gate, a memory cell MC7 that has the conductive layer WL2 as a control gate, and a memory cell MC8 that has the conductive layer WL1 as a control gate are provided.

The drain side selective transistor DST, the memory cells MC1 to MC4, the back gate transistor BGT, the memory cells MC5 to MC8, and the source side selective transistor SST are connected in series to configure one memory string. By arranging a plurality of memory strings in the X and Y directions, the plurality of memory cells MC1 to MC8 are three-dimensionally provided in the X, Y, and Z directions.

Next, the contact electrodes provided in the contact region 1b will be illustrated.

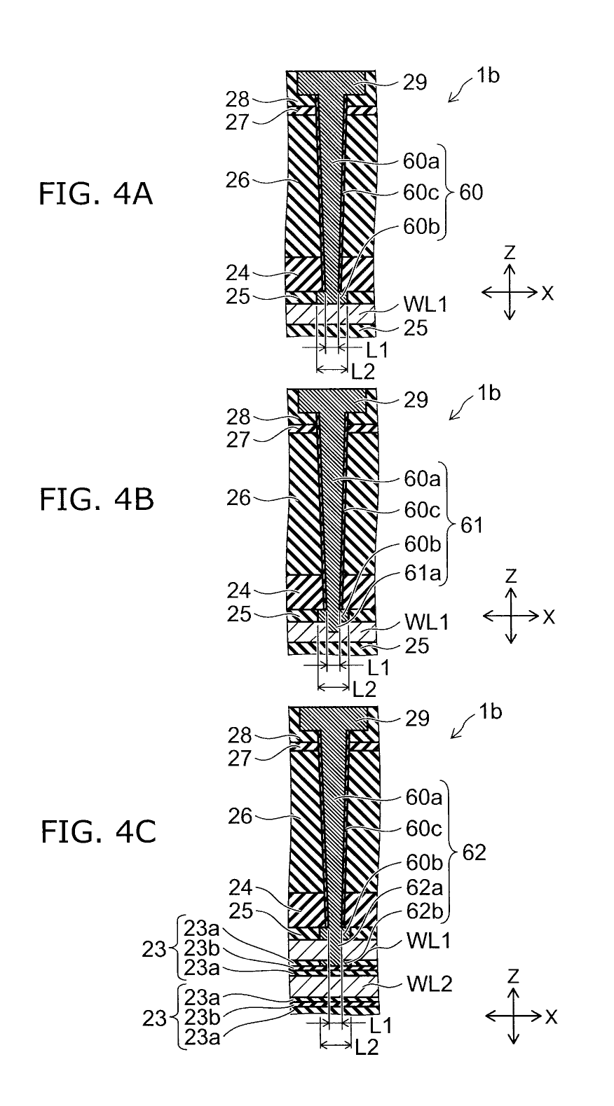

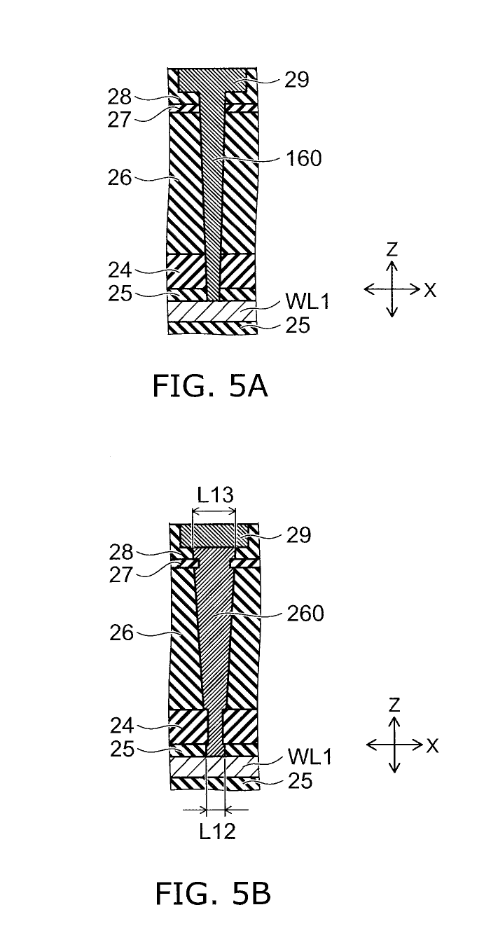

FIG. 4 is a schematic cross-sectional view for illustrating the contact electrode according to the embodiment. FIG. 5 is a schematic cross-sectional view for illustrating a contact electrode according to a comparative example.

As illustrated in FIG. 1, the contact region 1b is provided so as to be adjacent to the element region 1a illustrated in FIG. 2 in the X-direction. Therefore, similarly to the element region 1a, also in the contact region 1b, a back gate BG is provided on the substrate 10 through an insulating layer which is not illustrated, and a plurality of conductive layers WL1 to WL4 and a plurality of insulating layers 25 are alternately stacked on the back gate BG. Further, in the contact region 1b, edges of the conductive layers WL1 to WL4 are formed in a stepwise.

Further, in FIGS. 4 and 5, as an example, a contact electrode that is connected to one conductive layer formed in a stepwise will be illustrated. In FIGS. 4 and 5, the interlayer insulating layer which is omitted in FIG. 2 is illustrated as an insulating layer 25. The insulating layer 25 may be, for example, formed of a silicon oxide.

As illustrated in FIG. 4A, on the insulating layer 25 (the insulating layer 25 on the conductive layer WL1) which is the uppermost layer, insulating layers 24, 26, 27, and 28 are stacked in this order.

The insulating layers 24 and 27 may be, for example, formed of a silicon nitride.

The insulating layers 26 and 28 may be, for example, formed of a silicon oxide.

The contact electrode 60 extends in a stacked direction (Z-direction) of the stacked body formed of the insulating layers 25, 24, 26, 27, and 28 to reach the conductive layer WL1.

An upper layer interconnect 29 is buried in the insulating layer 28. The upper layer interconnect 29 is formed of a conductive material. The upper layer interconnect 29 may be formed using a metal having an excellent embeddability such as tungsten, copper, or ruthenium. However, the material of the upper layer interconnect 29 is not limited thereto, but may be appropriately changed.

In the contact electrode 60, a columnar portion 60a which extends in the stacked direction of the stacked body, a connection portion 60b (corresponding to an example of the first connection portion), and a stopper 60c are provided.

An upper edge of the columnar portion 60a is connected to the upper layer interconnect 29 and the connection portion 60b is provided at the lower edge of the columnar portion 60a.

The columnar portion 60a illustrated in FIG. 4A has a reverse circular truncated cone shape whose cross-section dimension is gradually reduced in a direction orthogonal to the stacked direction of the stacked body from the upper edge to the lower edge. However, the shape is not limited thereto. For example, the cross-section dimension may be substantially constant from the upper edge to the lower edge or the cross-section dimension may be changed between the upper edge and the lower edge to form a step.

The lower edge of the connection portion 60b is in contact with the conductive layer WL1.

The cross-section dimension L2 of the connection portion 60b in the direction orthogonal to the stacked direction of the stacked body is larger than the cross-section dimension L1 of the lower edge of the columnar portion 60a. As will be described below, the connection portion 60b is integrally formed with the columnar portion 60a. Therefore, an electric resistance between the connection portion 60b and the conductive layer WL1 is higher than an electric resistance between the columnar portion 60a and the connection portion 60b. Specifically, if it is possible to reduce the electric resistance between the connection portion 60b and the conductive layer WL1, the electric resistance for the contact electrode 60 may be reduced.

In the embodiment, since the connection portion 60b is provided, it is possible to increase an area that is in contact with the conductive layer WL1. Therefore, it is possible to reduce the electric resistance between the connection portion 60b and the conductive layer WL1, eventually, the electric resistance for the contact electrode 60.

The stopper 60c is provided so as to cover the side of the columnar portion 60a.

The columnar portion 60a and the connection portion 60b are formed of a conductive material. The columnar portion 60a and the connection portion 60b are formed using a metal having an excellent embeddability such as tungsten, copper, or ruthenium. However, the material of the columnar portion 60a and the connection portion 60b is not limited thereto, but may be appropriately changed.

An etching rate of a material for the stopper 60c is lower than an etching rate of a material of the insulating layer 25. For example, the stopper 60c may be formed of a silicon nitride and the insulating layer 25 may be formed of a silicon oxide.

Here, the contact electrode is provided inside the hole formed by the etching. In this case, as a depth dimension of the hole becomes larger, the cross-section dimension of the lower edge may be smaller.

Therefore, as illustrated in FIG. 5A, the contact electrode 160 having a reverse circular truncated cone shape is easily formed. Since in the contact electrode 160, the cross-sectional area of the lower edge becomes small, the electric resistance between the contact electrode 160 and the conductive layer WL1 is increased.

In this case, as illustrated in FIG. 5B, it is possible to increase the cross-section dimension L12 of the lower edge of the contact electrode 260 using a wet etching method. However, if the cross-section dimension L12 of the lower edge of the contact electrode 260 is increased only by the wet etching method, a cross-section dimension L13 of the upper edge of the contact electrode 260 is also increased. If the cross-section dimension L13 of the upper edge of the contact electrode 260 is increased, the dimension between the contact electrode 260 and an adjacent contact electrode 260 needs to be increased, which may hinder the miniaturization of the semiconductor device 1 or restrict to dispose the contact electrode 260.

In the embodiment, the stopper 60c is provided so as to cover the side of the columnar portion 60a. Further, an etching rate of a material for the stopper 60c is lower than an etching rate of a material for the insulating layer 25.

As will be described below, the insulating layer 25 is etched and the connection portion 60b may be formed in a portion where the insulating layer 25 is etched. In this case, since the etching rate of a material for the stopper 60c is lower than the etching rate of a material for the insulating layer 25, the material of the stopper is not removed when the insulating layer 25 is etched. Therefore, when the insulating layer 25 is etched, it is possible to suppress the cross-section dimension of the upper edge of the columnar portion 60a from being increased.

Further, the forming of the columnar portion 60a, the connection portion 60b, and the stopper 60c will be described below in detail.

As illustrated in FIG. 4B, the columnar portion 60a, the connection portion 60b, the stopper 60c, a protrusion portion 61a (corresponding to an example of a first protrusion portion) are provided in the contact electrode 61.

The protrusion portion 61a is further provided at the lower edge of the connection portion 60b. The protrusion portion 61a protrudes from the lower edge of the connection portion 60b and is buried inside the conductive layer WL1.

A lower surface of the connection portion 60b, and a side surface and a lower surface of the protrusion portion 61a are in contact with the conductive layer WL1.

Further, the connection portion 60b and the protrusion portion 61a are integrally formed with the columnar portion 60a. A material for the protrusion portion 61a may be the same as a material for the connection portion 60b.

In the embodiment, since the protrusion portion 61a is further provided, an area that is in contact with the conductive layer WL1 is increased as much as the protrusion portion 61a. Therefore, an electric resistance between the connection portion 60b and the protrusion portion 61a and the conductive layer WL1, eventually, an electric resistance for the contact electrode 61 may be further reduced.

As illustrated in FIG. 4C, in the contact electrode 62, the columnar portion 60a, the connection portion 60b, the stopper 60c, a protrusion portion 62a (corresponding to an example of a second protrusion portion), and a connection portion 62b (corresponding to an example of a second connection portion) are provided.

At the lower edge of the connection portion 60b, the protrusion portion 62a is provided. The protrusion portion 62a protrudes from the lower edge of the connection portion 60b and passes through the conductive layer WL1.

At the lower edge of the protrusion portion 62a, the connection portion 62b that is in contact with the conductive layer WL1 is provided.

An insulating layer 23 is provided between the conductive layers WL1 to WL4. The insulating layer 23 has an ONO (oxide-nitride-oxide) structure in which a silicon nitride layer 23b is interposed between a pair of silicon dioxide layers 23a. The lower surface of the connection portion 62b is in contact with the silicon nitride layer 23b. The silicon nitride layer 23b becomes a stopper when the connection portion 62b is formed.

The lower surface of the connection portion 60b, the side surface of the protrusion portion 62a, and the upper surface of the connection portion 62b are in contact with the conductive layer WL1.

The cross-section dimensions L2 of the connection portion 60b and the connection portion 62b in a direction orthogonal to the stacked direction of the stacked body are larger than the cross-section dimension L1 of the lower edge of the columnar portion 60a. Further, the connection portion 60b, the protrusion portion 62a, and the connection portion 62b are integrally formed with the columnar portion 60a. A material for the protrusion portion 62a and the connection portion 62b may be the same as the material for the connection portion 60b.

Further, in FIG. 4C, it is illustrated that the cross-section dimensions of the connection portion 60b and the connection portion 62b in the direction orthogonal to the stacked direction of the stacked body are equal to each other, but the cross-section dimensions of the connection portion 60b and the connection portion 62b in the direction orthogonal to the stacked direction of the stacked body may be different from each other.

In the embodiment, since the protrusion portion 62a and the connection portion 62b are further provided, the area that is in contact with the conductive layer WL1 may be increased as much as the protrusion portion 62a and the connection portion 62b. Therefore, the electric resistance between the connection portion 60b, the protrusion portion 62a, and the connection portion 62b and the conductive layer WL1, eventually, the electric resistance for the contact electrode 62 may be further reduced.

Contact electrodes 60, 61, and 62 and the conductive layer WL1 are configured as described above, the relationship between the contact electrodes 60, 61, and 62 and the conductive layers WL2 to WL4 are also configured same as the above description.

For example, in the contact region 1b, the stacked conductive layers WL1 to WL4 may be formed in a stepwise in order to connect the plurality of stacked conductive layers WL1 to WL4 with the upper layer interconnect. Specifically, the conductive layers become longer as the conductive layers WL1 to WL4 become lower layers.

In such a case, the connection portion 60b, the protrusion portion 61a, the protrusion portion 62a, and the connection portion 62b may be provided in a portion where the conductive layers WL2 to WL4 are exposed by protruding from a conductive layer which is the upper layer in a portion formed in a stepwise.

In this case, an etching rate of a material for a layer (insulating layer 24) provided on the connection portion 60b is lower than an etching rate of the material for the insulating layer 25.

Further, for example, as illustrated in FIG. 4C, when the insulating layer 23 where the silicon nitride layer 23b is interposed between the pair of silicon dioxide layers 23a is provided, but the stacked conductive layers WL1 to WL4 are not formed in a stepwise, the columnar portion 60a and the stopper 60c that pass through a layer positioned on the conductive layer which is a connecting target are provided and the connection portion 60b, the protrusion portion 61a, the protrusion portion 62a, and the connection portion 62b may be provided in the conductive layers WL1 to WL4 which are connecting targets.

In this case, an etching rate of the material for a layer (insulating layer 24) that is provided on the connection portion 60b formed on the uppermost conductive layer WL1 becomes lower than an etching rate of the material for the insulating layer 25.

Further, an etching rate of the material for a layer (silicon nitride layer 23b) that is provided on the connection portion 60b formed on the conductive layers WL2 to WL4 becomes lower than an etching rate of the material for the silicon dioxide layer 23a.

### Second Embodiment

Next, a method of manufacturing a semiconductor device 1 according to a second embodiment will be illustrated.

As described above, in the semiconductor device 1, the element region 1a, the contact region 1b, a peripheral circuit region which is not illustrated, or the upper layer interconnects are provided. However, a known technology may be applied to form elements provided in regions other than the contact region 1b. Therefore, here, it is mainly illustrated to form the elements provided in the contact region 1b.

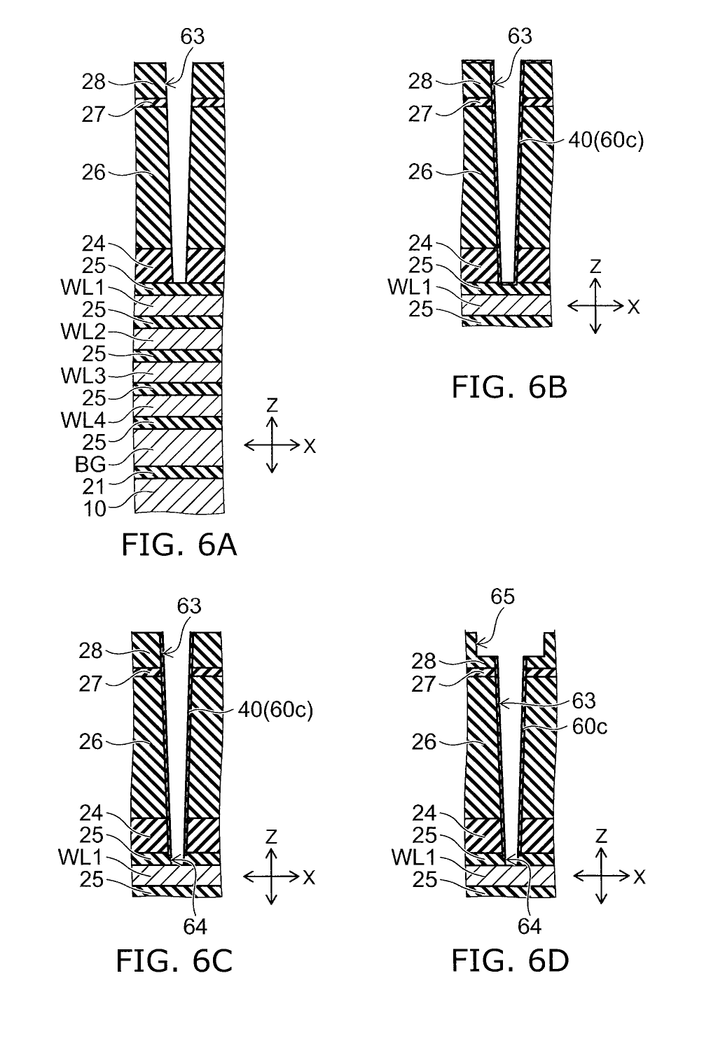

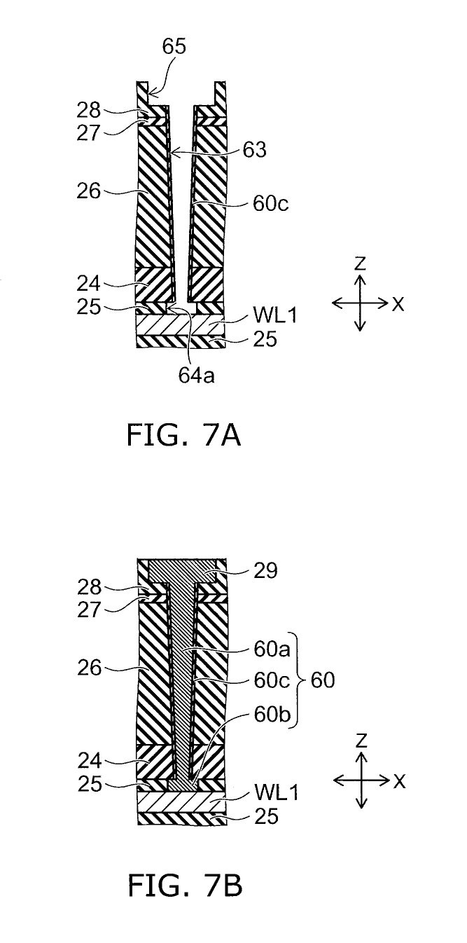

FIGS. 6 and 7 are schematic process cross-sectional views for illustrating the forming of elements provided in the contact region 1b.

Further, as an example, FIGS. 6 and 7 illustrate that a contact electrode 60 that is connected with a conductive layer WL1 is formed.

In the subsequent drawings to FIG. 6B, the lower layers than the conductive layer WL2 will be omitted.

First, as illustrated in FIG. 6A, an insulating layer 21 is formed on a substrate 10 and a back gate BG is formed on the insulating layer 21. A plurality of insulating layers 25 and conductive layers WL1 to WL4 are alternately stacked on the back gate BG and insulating layers 24, 26, 27, and 28 are stacked in this order on the stacked insulating layers 25 and conductive layers WL1 to WL4.

The insulating layer 21, the back gate BG, the insulating layer 25, the conductive layers WL1 to WL4, the insulating layers 24, 26, 27, and 28 may be formed using, for example, a CVD (chemical vapor deposition) method.

In this case, the insulating layers 21, 25, 26, and 28 are formed of a silicon oxide, the insulating layers 24 and 27 are formed of a silicon nitride, and the back gate BG and the conductive layers WL1 to WL4 are formed of silicon to which boron B is added.

Continuously, a hole 63 (corresponding to an example of a first hole) that passes through the insulating layers 28, 27, 26, and 24 and reaches the uppermost insulating layer 25 is formed.

In other words, when the contact electrode 60 that is connected to the conductive layers WL1 to WL4 is formed, a plurality of holes 63 that extend so as to face the corresponding conductive layers WL1 to WL4 are formed. The holes 63 may be formed, for example, by a photolithographic method or an RIE (reactive ion etching) method.

Next, as illustrated in FIG. 6B, a film 40 which will be a stopper 60c is formed so as to cover inner walls of the holes 63. In this case, the film 40 is formed on the upper surface of the insulating layer 28 and the bottom surface of the hole 63.

The film 40 may be formed, for example, by a CVD method.

In this case, a material having an etching rate lower than an etching rate of a material for the insulating layer 25 is used to form the film 40 which will be the stopper 60c. The film 40 is formed, for example, using a silicon nitride.

Next, as illustrated in FIG. 6C, the film 40 that is formed on the top surface of the insulating layer 28 and the bottom surface of the hole 63 is removed using the RIE method and a hole 64 (corresponding to an example of a second hole) that passes through the bottom surface of the hole 63 and reaches the conductive layer WL1 is formed.

Next, as illustrated in FIG. 6D, a groove 65 for forming an upper layer interconnect 29 is formed using the photolithographic method and the RIE method. By forming the groove 65, the stopper 60c is formed.

Next, as illustrated in FIG. 7A, by increasing a cross-section dimension of the hole 64 in a direction orthogonal to a stacked direction of the stacked body, a space 64a for forming a connection portion 60b is formed.

In other words, a cross-section dimension of the hole 64 between a lower edge of the hole 63 and the conductive layer WL1 becomes larger than a cross-section dimension of the lower edge of the hole 63.

For example, using a wet etching method that uses a diluted hydrofluoric acid, the space 64a is formed by removing the insulating layer 25 around the hole 64.

In this case, since the insulating layer 25 is formed of a silicon dioxide and the insulating layer 24 and the stopper 60c (film 40) are formed of a silicon nitride, the insulating layer 25 is removed to form the space 64a without removing the insulating layer 24 and the stopper 60c.

Therefore, it is possible to suppress a cross-section dimension of the upper edge (upper edge of the columnar portion 60a) of the stopper 60c from being increased.

Next, as illustrated in FIG. 7B, by burying a conductive material on the inside of the groove 65, in an inner side of the stopper 60c, and on the inside of a portion (space 64a) in which a cross-section dimension of the hole 64 is increased, the upper layer interconnect 29, the columnar portion 60a, and the connection portion 60b are integrally formed with each other.

For example, by burying the conductive material on the inside of the groove 65, in the inner side of the stopper 60c, and on the inside of the space 64a using a CVD method and removing a remaining portion formed on the upper surface of the insulating layer 28 using the RIE method, the upper layer interconnect 29, the columnar portion 60a, and the connection portion 60b are formed.

The upper layer interconnect 29, the columnar portion 60a, and the connection portion 60b may be formed of a metal such as tungsten, copper, or ruthenium.

As described above, the contact electrode 60 illustrated in FIG. 4A is formed.

Next, it is illustrated that a contact electrode 61 illustrated in FIG. 4B is formed.

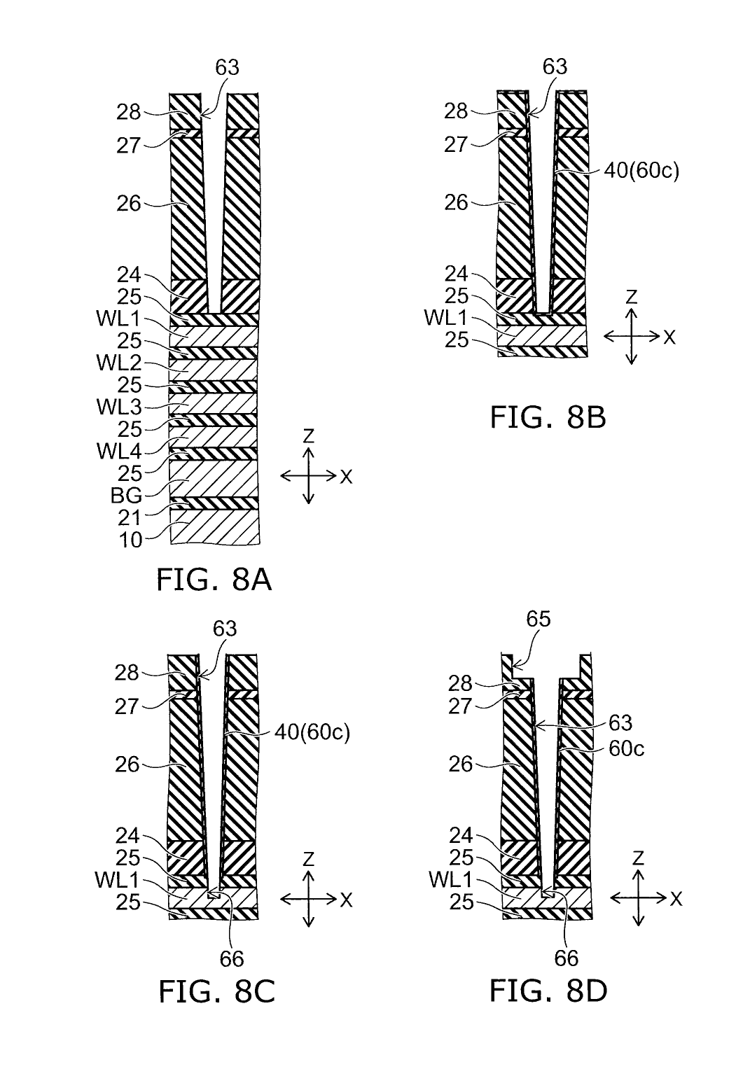

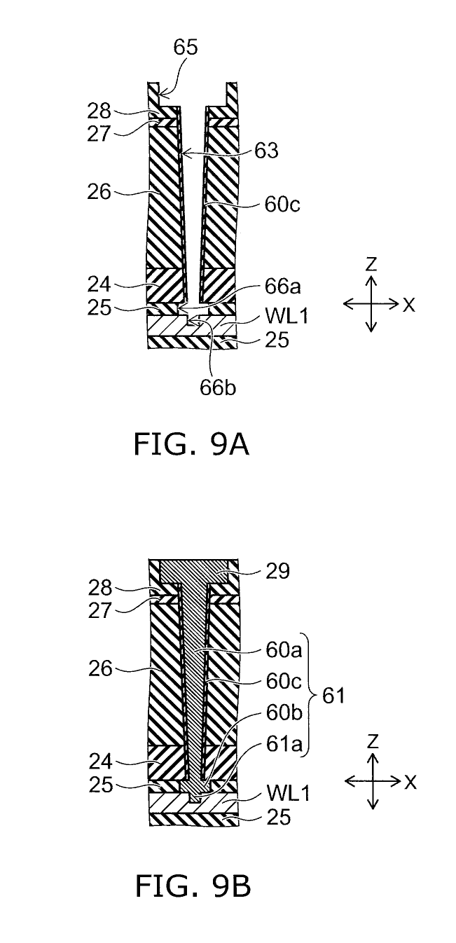

FIGS. 8 and 9 are schematic process cross-sectional views for illustrating the forming of elements provided in the contact region 1b.

Further, as an example, FIGS. 8 and 9 illustrate that a contact electrode 61 that is connected with a conductive layer WL1 is formed.

In the subsequent drawings to FIG. 8B, the lower layers than the conductive layer WL2 will be omitted.

First, as illustrated in FIG. 8A, an insulating layer 21 is formed on a substrate 10 and a back gate BG is formed on the insulating layer 21. A plurality of insulating layers 25 and conductive layers WL1 to WL4 are alternately stacked on the back gate BG and insulating layers 24, 26, 27, and 28 are formed in this order on the stacked insulating layers 25 and conductive layers WL1 to WL4. Continuously, a hole 63 is formed.

Further, since the insulating layer 21, the back gate BG, the insulating layer 25, the conductive layers WL1 to WL4, the insulating layers 24, 26, 27, and 28, and the hole 63 are formed as same as those illustrated in FIG. 6A, the detailed description thereof will be omitted.

Next, as illustrated in FIG. 8B, a film 40 which will be a stopper 60c is formed so as to cover an inner wall of the hole 63.

Further, since the film 40 is formed as same as illustrated in FIG. 6B, the detailed description thereof will be omitted.

Next, as illustrated in FIG. 8C, the film 40 that is formed on the top surface of the insulating layer 28 and the bottom surface of the hole 63 is removed using the RIE method and a hole 66 (corresponding to an example of a second hole) that passes through the bottom surface of the hole 63 and reaches the conductive layer WL1 is formed.

Next, as illustrated in FIG. 8D, a groove 65 for forming an upper layer interconnect 29 is formed using the photolithographic method and the RIE method. By forming the groove 65, the stopper 60c is formed.

Next, as illustrated in FIG. 9A, by increasing a cross-section dimension of the hole 66 in a direction orthogonal to a stacked direction of the stacked body, a space 66a for forming a connection portion 60b is formed. Further, a space 66b for forming a protrusion portion 61a protruding from a lower edge of the connection portion 60b is formed.

For example, using a wet etching method that uses a diluted hydrofluoric acid, the space 66a is formed by removing the insulating layer 25 around the hole 66.

In this case, the insulating layer 25 may be formed of a silicon oxide, the insulating layer 24 and the stopper 60c (film 40) may be formed of a silicon nitride, and the conductive layer WL1 may be formed of silicon to which an impurity such as boron is added. Accordingly, the insulating layer 25 between the conductive layer WL1 and the insulating layer 24 is removed to form the space 66a without removing the insulating layer 24, the stopper 60c, and the conductive layer WL1.

Further, a space remaining in the conductive layer WL1 becomes a space 66b.

In this case, since the stopper 60c is not removed, it is possible to suppress the cross-section dimension of the upper edge (upper edge of the columnar portion 60a) of the stopper 60c from being increased.

Next, as illustrated in FIG. 9B, by burying a conductive material on the inside of the groove 65, in an inner side of the stopper 60c, on the inside of the space 66a, and on the inside of the space 66b, the upper layer interconnect 29, the columnar portion 60a, the connection portion 60b, and the protrusion portion 61a are integrally formed with each other.

For example, by burying the conductive material on the inside of the groove 65, in the inner side of the stopper 60c, on the inside of the space 66a, and on the inside of the space 66b using a CVD method and removing a remaining portion formed on the upper surface of the insulating layer 28 using the RIE method, the upper layer interconnect 29, the columnar portion 60a, the connection portion 60b, and the protrusion portion 61a are formed.

The upper layer interconnect 29, the columnar portion 60a, the connection portion 60b, and the protrusion portion 61a may be formed of a metal such as tungsten, copper, or ruthenium.

As described above, the contact electrode 61 illustrated in FIG. 4B is formed.

Next, it is illustrated that a contact electrode 62 illustrated in FIG. 4C is formed.

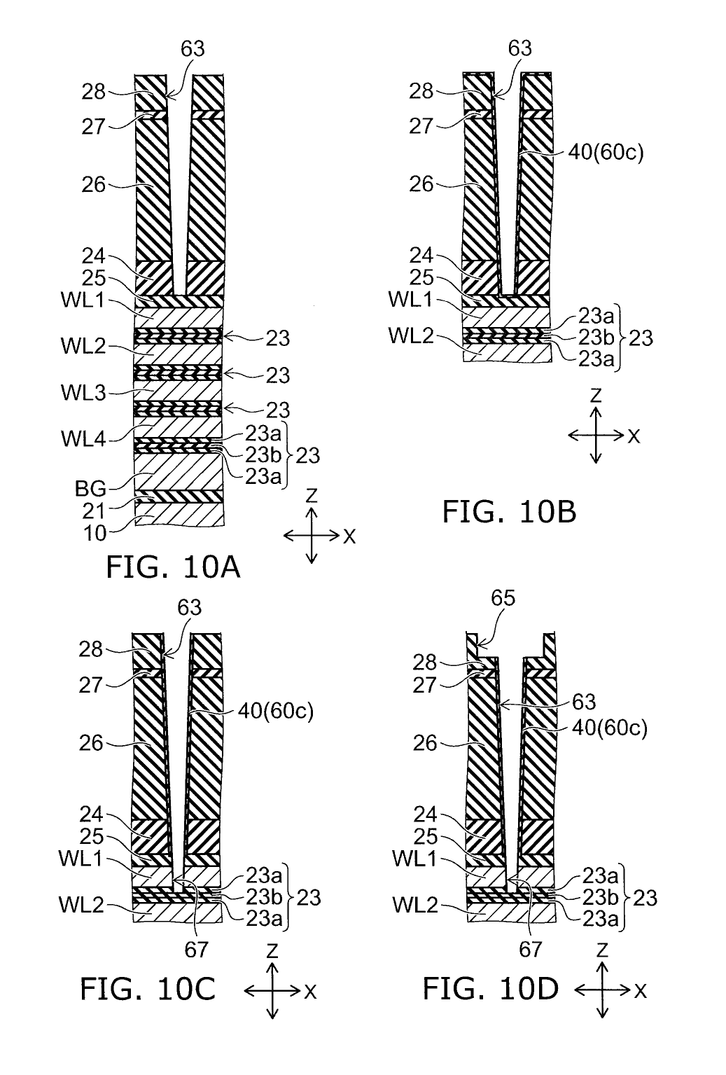

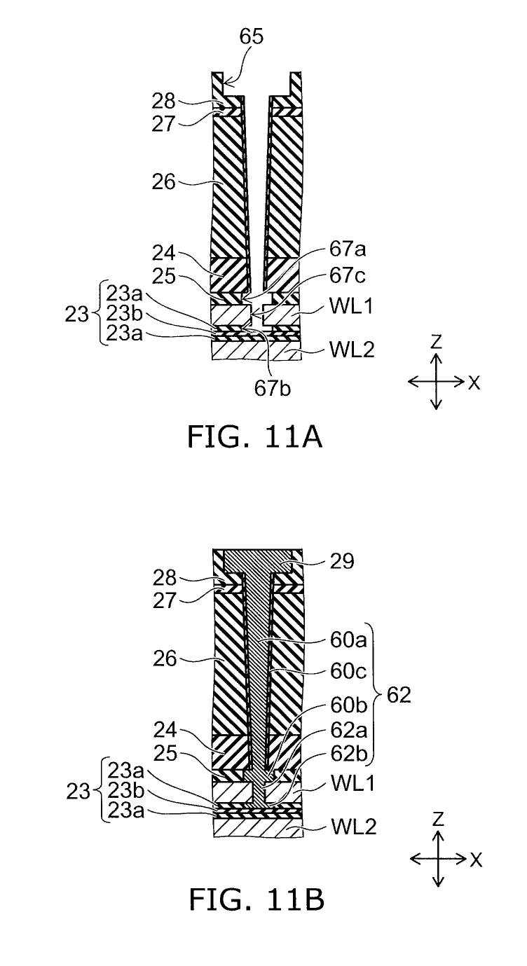

FIGS. 10 and 11 are schematic process cross-sectional views for illustrating the forming of elements provided in the contact region 1b.

Further, as an example, FIGS. 10 and 11 illustrate that a contact electrode 62 that is connected with a conductive layer WL1 is formed.

In the subsequent drawings to FIG. 10B, the lower layers than the conductive layer WL2 will be omitted.

First, as illustrated in FIG. 10A, an insulating layer 21 is formed on a substrate 10 and a back gate BG is formed on the insulating layer 21. A plurality of insulating layers 23 and conductive layers WL1 to WL4 are alternately stacked on the back gate BG and insulating layers 25, 24, 26, 27, and 28 are formed in this order on the stacked insulating layers 23 and conductive layers WL1 to WL4. Continuously, a hole 63 is formed.

In this case, the insulating layer 23 may be formed, for example, by stacking a silicon dioxide layer 23a, a silicon nitride layer 23b, and the silicon dioxide layer 23a in this order using a CVD method.

A sacrificial layer is formed instead of the insulating layer 23, the sacrificial layer is removed through a hole which is not illustrated, the silicon dioxide layer 23a is formed in a portion where the sacrificial layer is removed through a hole which is not illustrated, and the silicon nitride layer 23b may be formed between the silicon dioxide layers 23a. In this case, the sacrificial layer may be formed of polysilicon to which no impurity is added. The sacrificial layer may be removed using a wet etching method that uses, for example, choline aqueous solution (TMY). The silicon dioxide layer 23a and the silicon nitride layer 23b may be formed using, for example, an ALD (atomic layer deposition) method.

Since the insulating layer 21, the back gate BG, the conductive layers WL1 to WL4, the insulating layers 25, 24, 26, 27, and 28, and the hole 63 are formed as same as those illustrated in FIG. 6A, the detailed description thereof will be omitted.

Next, as illustrated in FIG. 10B, a film 40 which will be a stopper 60c is formed so as to cover an inner wall of the hole 63.

Further, since the film 40 is formed as same as illustrated in FIG. 6B, the detailed description thereof will be omitted.

Next, as illustrated in FIG. 10C, the film 40 that is formed on the top surface of the insulating layer 28 and the bottom surface of the hole 63 is removed using the RIE method and a hole 67 (corresponding to an example of a second hole) that passes through the bottom surface of the hole 63 to reach the silicon nitride layer 23b provided in the insulating layer 23 positioned below the conductive layer WL1 is formed. In other words, the hole 67 passes through the corresponding conductive layer WL1 and reaches the silicon nitride layer 23b.

Next, as illustrated in FIG. 10D, a groove 65 for forming an upper layer interconnect 29 is formed using the photolithographic method and the RIE method. By forming the groove 65, the stopper 60c is formed.

Next, as illustrated in FIG. 11A, by increasing a cross-section dimension of the hole 67 in a direction orthogonal to a stacked direction of the stacked body, a space 67a for forming a connection portion 60b and a space 67b for forming a connection portion 62b are formed. Further, a space 67c for forming a protrusion portion 62a protruding from a lower edge of the connection portion 60b is formed.

In other words, the cross-section dimension of the hole 67 between the lower edge of the hole 63 and the corresponding conductive layer WL1 and the cross-section dimension of the hole 67 positioned below the conductive layer WL1 become larger than the cross-section dimension of the lower edge of the hole 63.

For example, using a wet etching method that uses a diluted hydrofluoric acid, the space 67a is formed by removing the insulating layer 25 around the hole 67. Further, the space 67b is formed by removing the silicon dioxide layer 23a around the hole 67.

In this case, the insulating layer 25 and the silicon dioxide layer 23a may be formed of a silicon oxide, the insulating layer 24, the stopper 60c (film 40) and the silicon nitride layer 23b may be formed of a silicon nitride, and the conductive layer WL1 may be formed of silicon to which an impurity such as boron is added. Accordingly, the insulating layer 25 between the conductive layer WL1 and the insulating layer 24 is removed to form the space 67a without removing the insulating layer 24, the stopper 60c, the silicon nitride layer 23b, and the conductive layer WL1.

Further, the silicon dioxide layer 23a between the conductive layer WL1 and the silicon nitride layer 23b is removed to form the space 67b.

In addition, a space remaining in the conductive layer WL1 becomes a space 67c.

In this case, since the stopper 60c is not removed, it is possible to suppress the cross-section dimension of the upper edge (upper edge of the columnar portion 60a) of the stopper 60c from being increased.

Next, as illustrated in FIG. 11B, by burying a conductive material on the inside of the groove 65, in an inner side of the stopper 60c, on the inside of the space 67a, on the inside of the space 67b, and on the inside of the space 67c, the upper layer interconnect 29, the columnar portion 60a, the connection portion 60b, the protrusion portion 62a, and the connection portion 62b are integrally formed with each other.

For example, by burying the conductive material on the inside of the groove 65, in the inner side of the stopper 60c, on the inside of the space 67a, on the inside of the space 67b, and on the inside of the space 67c using a CVD method and removing a remaining portion formed on the upper surface of the insulating layer 28 using the RIE method, the upper layer interconnect 29, the columnar portion 60a, the connection portion 60b, the protrusion portion 62a, and the connection portion 62b are formed.

The upper layer interconnect 29, the columnar portion 60a, the connection portion 60b, the protrusion portion 62a, and the connection portion 62b may be formed of a metal such as tungsten, copper, or ruthenium.

As described, the contact electrode 62 illustrated in FIG. 4C may be formed.

Even though the contact electrodes 60, 61, and 62 and the conductive layer WL1 are configured as described above, the contact electrodes 60, 61, and 62 and the conductive layers WL2 to WL4 may be configured as same as the above description.

For example, in order to connect the plurality of stacked conductive layers WL1 to WL4 to the upper layer interconnect, the stacked conductive layers WL1 to WL4 may be processed in a stepwise and the connection portion 60b, the protrusion portion 61a, the protrusion portion 62a, and the connection portion 62b may be formed in a portion that is exposed as the conductive layers WL2 to WL4 protrude from the conductive layer which is an upper layer. Further, a known technology may be applied to process the stacked conductive layers WL1 to WL4 in a stepwise and thus the description about the processing of the stacked conductive layers WL1 to WL4 in a stepwise will be omitted.

Further, when the stacked conductive layers WL1 to WL4 are not processed in a stepwise, the columnar portion 60a and the stopper 60c that pass through a layer disposed above the conductive layer which is the connecting target are formed and the connection portion 60b, the protrusion portion 61a, the protrusion portion 62a, and the connection portion 62b may be formed in the conductive layers WL1 to WL4 which are the connecting targets.

According to a method of manufacturing a semiconductor device according to the embodiment, it is possible to easily manufacture a semiconductor device that is capable of reducing an electric resistance between the contact electrode and the conductive layer.

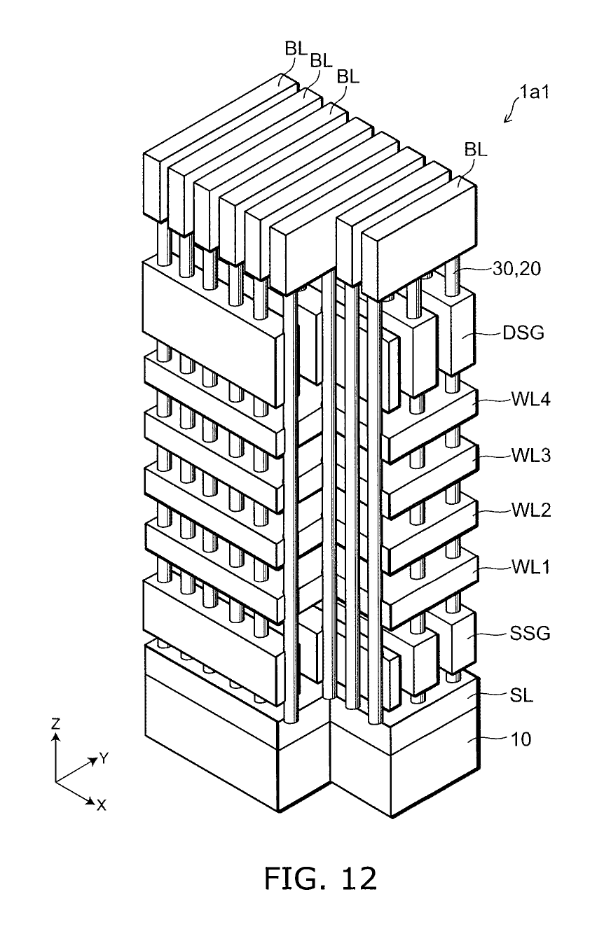

FIG. 12 is a schematic perspective view for illustrating another configuration of an element region 1a1 provided in the semiconductor device 1 according to the first embodiment.

In FIG. 12, in order to simplify the drawing, an insulated part is omitted but only conductive part is illustrated.

In FIG. 2, the U-shaped memory strings are illustrated. In contrast, in FIG. 12, I-shaped memory strings may be used.

In the above structure, a source line SL is provided on the substrate 10, and a source side selective gate (or lower selective gate) SSG is provided thereabove. Further, the conductive layers WL1 to WL4 are provided thereabove and a drain side selective gate (or upper selective gate) DSG is provided between the uppermost conductive layer WL1 and the bit line BL.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, above-mentioned embodiments can be combined mutually and can be carried out.

What is claimed is:

1. A semiconductor device, comprising:
a stacked body in which a plurality of conductive layers and a plurality of first insulating layers are alternately stacked; and a plurality of contact electrodes that reach corresponding conductive layers,
wherein each of the contact electrodes includes a columnar portion that extends in a stacked direction of the stacked body, a stopper that covers the side of the columnar portion, and a first connection portion that is provided at a lower edge of the columnar portion and is in contact with the corresponding conductive layer,
a cross-section dimension of the first connection portion in a direction orthogonal to the stacked direction is larger than a cross-section of the lower edge of the columnar portion, and
an etching rate of a material for the stopper is lower than an etching rate of a material for the first insulating layer.

2. The device according to claim 1, wherein an etching rate of a material for a layer provided on the first connection portion is lower than an etching rate of a material for the first insulating layer.

3. The device according to claim 1, wherein the first connection portion is integrally formed with the columnar portion.

4. The device according to claim 1, wherein the contact electrode further includes a first protrusion portion that protrudes from the first connection portion and is buried inside the corresponding conductive layer.

5. The device according to claim 4, wherein the first protrusion portion is integrally formed with the first connection portion.

6. The device according to claim 1, wherein the contact electrode further includes:
a second protrusion portion that protrudes from the first connection portion and passes through the corresponding conductive layer; and
a second connection portion that is provided at the lower edge of the second protrusion portion and is in contact with the corresponding conductive layer.

7. The device according to claim 6, wherein a cross-section dimension of the second connection portion in a direction orthogonal to the stacked direction is larger than a cross-section dimension of the lower edge of the columnar portion.

8. The device according to claim 6, wherein the second protrusion portion is integrally formed with the first connection portion.

9. The device according to claim 6, wherein the second connection portion is integrally formed with the second protrusion portion.

10. The device according to claim 1, wherein the columnar portion has a shape in which a cross-sectional dimension in a direction orthogonal to the stacked direction is gradually reduced from the upper edge to the lower edge.

11. The device according to claim 1, wherein the stopper includes a silicon nitride.

12. The device according to claim 2, wherein the layer provided on the first connection portion includes a silicon nitride.

13. The device according to claim 1, further comprising:
an upper layer interconnect connected to the upper edge of the columnar portion.

14. A method of manufacturing a semiconductor device that includes a stacked body in which a plurality of conductive layers and a plurality of first insulating layers are alternately stacked and a plurality of contact electrodes that reach corresponding conductive layers, the method comprising:
alternately stacking the plurality of conductive layers and the plurality of first insulating layers;
forming a plurality of first holes extending toward the corresponding conductive layers;
forming a film which becomes a stopper in inner walls of the plurality of first holes;
forming a plurality of second holes that pass through bottom surfaces of the plurality of first holes to reach the corresponding conductive layers;
making cross-section dimensions of the second holes between lower edges of the plurality of first holes and the corresponding conductive layers be larger than cross-section dimensions of the lower edges of the first holes; and
burying a conductive material in an inner side of a film which becomes the stopper and inside the portion that makes the cross-section dimension of the second hole be larger,
wherein in the forming of a film which becomes the stopper in the inner walls of the plurality of first holes, the film which becomes the stopper is formed using a material having an etching rate lower than an etching rate of a material for the first insulating layer.

15. The method according to claim 14, wherein in the forming of the plurality of second holes that pass through the bottom surfaces of the plurality of first holes to reach the corresponding conductive layers, the plurality of second holes reach the inside of the corresponding conductive layers.

16. The method according to claim 14, wherein in the forming of the plurality of second holes that pass through the bottom surfaces of the plurality of first holes to reach the corresponding conductive layers, the plurality of second holes pass through the corresponding conductive layers, and
in the making of cross-section dimensions of the second holes between the lower edges of the plurality of first holes and the corresponding conductive layers be larger than cross-section dimensions of the lower edges of the first holes, the cross-section dimensions of the second holes between the lower edges of the plurality of first holes and the corresponding conductive layers and cross-section dimensions of the second holes positioned below the conductive layers are larger than cross-section dimensions of the lower edges of the first holes.

17. The method according to claim 14, wherein in the making of cross-section dimensions of the second holes between the lower edges of the plurality of first holes and the corresponding conductive layers be larger than cross-section dimensions of the lower edges of the first holes, the first insulating layers around the second holes are removed using a wet etching method.

18. The method according to claim 16, wherein in the making of cross-section dimensions of the second holes between the lower edges of the plurality of first holes and the corresponding conductive layers be larger than cross-section dimensions of the lower edges of the first holes, the first insulating layers around the second holes between the lower edges of the plurality of first holes and the corresponding conductive layers and a silicon dioxide layer around the second holes positioned below the conductive layers are removed using a wet etching method.

19. The method according to claim 14, wherein in the forming of a film which becomes a stopper in inner walls of the plurality of first holes, a film including a silicon nitride is formed.

20. The method according to claim 14, wherein in the alternately stacking of the plurality of conductive layers and the plurality of first insulating layers, the plurality of first insulating layers including a silicon oxide are formed.
